(19) United States
(12) Patent Application Publication
(10) Pub. No.: US 2024/0396529 A1
(43) Pub. Date: Nov. 28, 2024

(54) VOLTAGE AND CURRENT GENERATOR

(71) Applicants: Yokogawa Electric Corporation, Tokyo (JP); Yokogawa Test & Measurement Corporation, Tokyo (JP)

(72) Inventors: Yoshinobu Sugihara, Tokyo (JP); Naoto Tsuchida, Tokyo (JP)

(73) Assignees: Yokogawa Electric Corporation, Tokyo (JP); Yokogawa Test & Measurement Corporation, Tokyo (JP)

(21) Appl. No.: 18/667,097

(22) Filed: May 17, 2024

(30) Foreign Application Priority Data
May 22, 2023 (JP) 2023-083959

(51) Int. Cl. H03H 11/04; H03H 7/38; H03H 11/30

(52) U.S. Cl. CPC H03H 11/0472; H03H 7/38; H03H 11/30

(57) ABSTRACT

A voltage and current generator (1) includes an operation interface (11) that receives an operation from a user, an output stage (16) that outputs an electrical signal to a load (30), detectors (17, 18) that detect a measured value of the electrical signal outputted by the output stage (16), and a control calculator (15) that controls operation of the output stage (16), based on the deviation between a target value of the electrical signal as set by the user via the operation interface (11) and the measured value of the electrical signal as detected by the detector, so that the measured value of the electrical signal approaches the target value. The control calculator (15) performs control, including a compensation operation to cancel a low-pass filter effect in output resistance of the output stage (16) and the load (30), based on an impedance of the load (30) as set by the user via the operation interface (11).

### CROSS-REFERENCE TO RELATED APPLICATION

The present application claims priority to Japanese Patent Application No. 2023-083959 filed on May 22, 2023, the entire contents of which are incorporated herein by reference.

### TECHNICAL FIELD

The present disclosure relates to voltage and current generation for a source measure unit.

### BACKGROUND

A source measure unit (SMU) is a device that integrates the functions of generating (source) and measuring (measure) DC voltage and current. Source measure units can supply a constant voltage or constant current of a specified value to a load and can measure the actual voltage or current at the load. Generally, source measure units are used for characteristic evaluation, inspection, and the like of devices such as semiconductors and electronic components. In source measure units, a short settling time to target values is required in voltage and current generation to improve efficiency in evaluation and inspection. Patent Literature (PTL) 1 describes technology related to source measure units.

### CITATION LIST

### Patent Literature

PTL 1: U.S. Pat. No. 8,797,025 B2

### SUMMARY

A voltage and current generator according to several embodiments includes:
an operation interface configured to receive an operation from a user;
an output stage configured to output an electrical signal to a load;
a detector configured to detect a measured value of the electrical signal outputted by the output stage; and
a control calculator configured to control operation of the output stage, based on a deviation between a target value of the electrical signal as set by the user via the operation interface and the measured value of the electrical signal as detected by the detector, so that the measured value of the electrical signal approaches the target value, wherein
the control calculator is configured to perform control, including a compensation operation to cancel a low-pass filter effect in output resistance of the output stage and the load, based on an impedance of the load as set by the user via the operation interface.

### BRIEF DESCRIPTION OF THE DRAWINGS

In the accompanying drawings:

FIG. 1 is a diagram illustrating a configuration of a source measure unit according to a comparative example;

FIG. 2 is a block diagram illustrating an example configuration of a voltage and current generator according to an embodiment;

FIG. 3 is a diagram illustrating an example of a graph of an optimal output waveform in a source measure unit;

FIG. 4 is a diagram illustrating an example of a graph of an output waveform with overshooting and ringing in a source measure unit;

FIG. 5A is a diagram illustrating a circuit configuration corresponding to the impedance of a load;

FIG. 5B is a diagram illustrating a circuit configuration corresponding to the impedance of a load;

FIG. 6 is a diagram illustrating an example of a circuit that provides the inverse characteristics of a low-pass filter;

FIG. 7 is a diagram illustrating the gain characteristics of the load in FIG. 5A;

FIG. 8 is a diagram illustrating the gain characteristics of the circuit in FIG. 6; and

FIG. 9 is a diagram illustrating an example of optimizing the graph of the output waveform in FIG. 4.

### DETAILED DESCRIPTION

The source measure unit described in PTL 1 is difficult to operate, because it requires the user to set parameters that are difficult to calculate.

It would be helpful to achieve improved output response of the source measure unit with a simple setting.

A voltage and current generator according to several embodiments includes:
(1) an operation interface configured to receive an operation from a user;
an output stage configured to output an electrical signal to a load;
a detector configured to detect a measured value of the electrical signal outputted by the output stage; and
a control calculator configured to control operation of the output stage, based on a deviation between a target value of the electrical signal as set by the user via the operation interface and the measured value of the electrical signal as detected by the detector, so that the measured value of the electrical signal approaches the target value, wherein
the control calculator is configured to perform control, including a compensation operation to cancel a low-pass filter effect in output resistance of the output stage and the load, based on an impedance of the load as set by the user via the operation interface.

The user can therefore improve the output response of the voltage and current generator by simply setting the impedance of the load, without having to consider the output resistance of the output stage, which is difficult to know from the outside.

In an embodiment, (2) in the voltage and current generator of (1), the control calculator may be configured to perform the control, including the compensation operation to cancel the low-pass filter effect in the output resistance and the load, based on the output resistance of the output stage corresponding to a range of the electrical signal as set by the user via the operation interface.

The output response of the voltage and current generator can therefore be improved through precise control without the user having to set the output resistance, which is difficult for the user to know externally, that corresponds to the range.

In an embodiment, (3) in the voltage and current generator of (1) or (2),
the output stage may be configured to output a constant voltage signal as the electrical signal to the load,
the detector may be configured to detect a voltage value of the electrical signal outputted by the output stage as the measured value, and
the control calculator may be configured to
   control operation of the output stage based on a deviation between a target value of voltage of the electrical signal as set by the user via the operation interface and the voltage value of the electrical signal as detected by the detector, and
   perform control, including the compensation operation to cancel the low-pass filter effect in the output resistance and the load, based on a resistance and a capacitance of the load as set by the user via the operation interface as the impedance of the load.

The user can therefore improve the constant voltage output response of the voltage and current generator by performing a simple setting.

In an embodiment, (4) in the voltage and current generator of any one of (1) to (3),
the output stage may be configured to output a constant current signal as the electrical signal to the load,
the detector may be configured to detect a current value of the electrical signal outputted by the output stage as the measured value, and
the control calculator may be configured to
   control operation of the output stage based on a deviation between a target value of current of the electrical signal as set by the user via the operation interface and the current value of the electrical signal as detected by the detector, and
   perform control, including the compensation operation to cancel the low-pass filter effect in the output resistance and the load, based on a resistance and an inductance of the load as set by the user via the operation interface as the impedance of the load.

The user can therefore improve the constant current output response of the voltage and current generator by performing a simple setting.

In an embodiment, (5) in the voltage and current generator of any one of (1) to (4), as the control to cancel the low-pass filter effect in the load, the control calculator may be configured to perform control adjusted to add a characteristic limiting a maximum gain for the electrical signal in a band greater than a predetermined frequency.

The operation of the voltage and current generator can therefore be prevented from becoming unstable even in a case in which no load is connected to the voltage and current generator.

According to an embodiment of the present disclosure, improved output response of the source measure unit can be achieved with a simple setting.

### Comparative Example

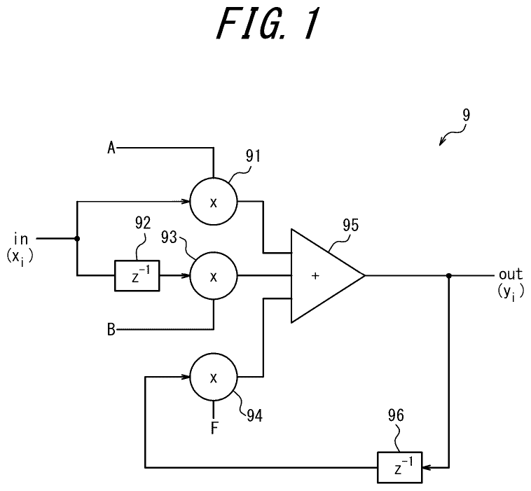

FIG. 1 is a diagram illustrating a configuration of an SMU 9 according to a comparative example (PTL 1). A user accesses the SMU 9 via a user interface and inputs three desired values corresponding to gain bandwidth (GBW), compensation frequency, and pole/zero ratio. GBW corresponds to how high the gain of the integrator is. The compensation frequency corresponds to the geometric mean of the pole frequency and the zero frequency. The pole/zero ratio corresponds to the ratio between the pole frequency and the zero frequency.

The SMU 9 in FIG. 1 compensates the feedback loop using parameters A, B, and F, which are determined from the values inputted by the user for GBW, compensation frequency, and pole/zero ratio. As illustrated in FIG. 1, the input signal xᵢ (representing the i^{th} sample) is inputted to a multiplier block 91 and a delay 92. The multiplier block 91 multiplies the input signal xᵢ by the parameter A. The output of the delay 92 is inputted to a multiplier block 93. The multiplier block 93 multiplies the output of the delay 92 by the parameter B. An adder 95 takes the output of the multiplier block 91, the output of the multiplier block 93, and the output of the multiplier block 94 as input. The output of the adder 95 is provided to the delay 96 as a feedback signal. The multiplier block 94 multiplies the output of the delay 96 by the parameter F.

The default values for A, B, and F are calculated based on the default values loaded into the SMU 9 and are then changed by the user. The SMU 9 makes the GBW, compensation frequency, and pole/zero ratio of the digital feedback loop programmable, thereby allowing the compensation to be freely adjusted for specific loads, suppressing overshooting and ringing, and shortening the settling time.

However, the configuration according to the comparative example requires the input of parameters such as GBW, compensation frequency, and pole/zero ratio, which are difficult to calculate in a non-intuitive manner. In addition, the output resistance of the output stage in the apparatus must also be considered in order for the user to find the appropriate setting values, yet such output resistance is information that is generally not disclosed to the user. In a case in which the output resistance of the output stage changes, such as during a range change, the optimal adjustment state cannot be maintained. The configuration according to the comparative example thus requires the setting of parameters that are difficult to calculate and is therefore difficult to operate.

### Embodiment

An embodiment of the present disclosure is now described with reference to the drawings. Portions having an identical configuration or function in the drawings are labeled with the same reference signs. In the explanation of the embodiments, a redundant description of identical portions may be omitted or simplified as appropriate.

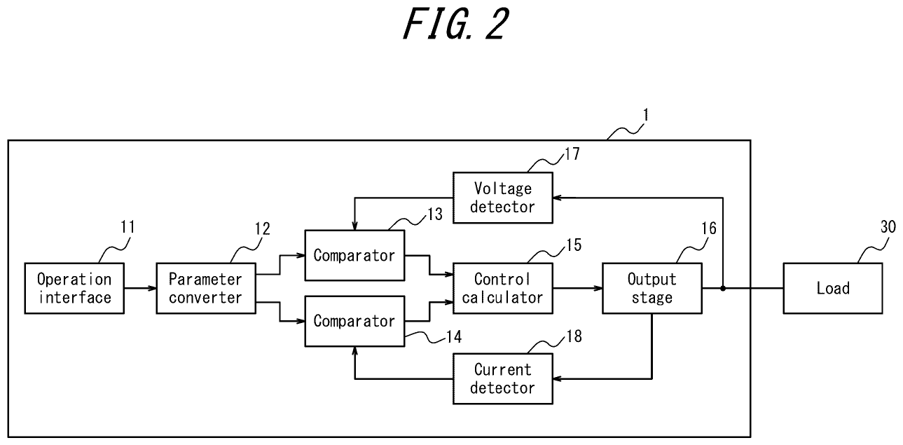

FIG. 2 is a block diagram illustrating an example configuration of a voltage and current generator 1 according to an embodiment. The voltage and current generator 1 generates an electrical signal, with the voltage or current settled to a target value, for the load 30. As illustrated in FIG. 2, the voltage and current generator 1 includes an operation interface 11, a parameter converter 12, comparators 13, 14, a control calculator 15, an output stage 16, a voltage detector 17, and a current detector 18.

Although the voltage and current generator 1 can be realized as a source measure unit, FIG. 2 omits the configuration other than that for settling the voltage or current to a target value. For example, FIG. 2 omits a calculator that averages the measured values of the voltage or current, a memory for storing, a display for displaying to the user, and the like. Furthermore, although FIG. 2 illustrates control lines for setting target values from the parameter converter 12 to the comparators 13, 14, for example, other control lines may be present. Specifically, control lines related to range control and output on/off control may be connected from the parameter converter 12 to the blocks to be controlled.

The operation interface 11 accepts settings from the user for operating information, such as a target value of voltage or current, the impedance of the load 30 (inductance L₁, capacitance C₁, and resistance R₃), and a range. The operation interface 11 may, for example, include an input interface such as buttons, switches, and a touch panel, along with a display that displays the calculation results of the voltage and current generator 1 and other information. The operation interface 11 outputs the setting values to the parameter converter 12.

The parameter converter 12 converts the values accepted by the operation interface 11 into internal information and sets the internal information for each constituent element, including the comparators 13, 14.

The comparators 13, 14 calculate the deviation between the target value and a feedback value. The comparator 13 calculates the deviation between the target value and the feedback value with respect to the voltage. The comparator 14 calculates the deviation between the target value and the feedback value with respect to the current. The comparators 13 and 14 output the calculated deviations to the control calculator 15.

The control calculator 15 selects either a voltage deviation or a current deviation and also performs phase compensation of the control loop. As described below, the control calculator 15 controls the output based on the impedance of the load 30.

The output stage 16 receives the output of the control calculator 15 and electrically drives the output terminal to the load 30. The output stage 16 outputs the output voltage to the voltage detector 17. The output stage 16 includes a current detection resistor (shunt resistor) inserted in series with the output wiring and outputs the potential difference between the two ends of the current detection resistor to the current detector 18.

The voltage detector 17 scales, by range, and quantifies the signal proportional to the output voltage. The voltage detector 17 outputs the signal of the quantified output voltage to the comparator 13.

The current detector 18 scales, by range, and quantifies the signal proportional to the output current. The current detector 18 outputs the signal of the quantified output current to the comparator 14.

The load 30 is connected to the output stage 16 of the voltage and current generator 1 through the output terminal of the voltage and current generator 1.

The following is an outline of the operation of constant voltage output by the voltage and current generator 1. The operation interface 11 accepts setting information from the user and outputs a voltage setting value to the parameter converter 12. The parameter converter 12 converts the voltage setting value into internal information and outputs a voltage target value to the comparator 13. The comparator 13 compares the voltage target value with the output of the voltage detector 17 and outputs a voltage deviation to the control calculator 15. The control calculator 15 selects the voltage deviation, performs phase compensation of the control loop, and outputs a control value to the output stage 16. The output stage 16 receives the output of the control calculator 15 and electrically drives the load 30. The voltage detector 17 quantifies a signal proportional to the voltage outputted from the output stage 16 and outputs the result to the comparator 13.

The following is an outline of the operation of constant current output by the voltage and current generator 1. The operation interface 11 accepts setting information from the user and outputs a current setting value to the parameter converter 12. The parameter converter 12 converts the current setting value into internal information and outputs a current target value to the comparator 14. The comparator 14 compares the current target value with the output of the current detector 18 and outputs a current deviation to the control calculator 15. The control calculator 15 selects the current deviation, performs phase compensation of the control loop, and outputs a control value to the output stage 16. The output stage 16 receives the output of the control calculator 15 and electrically drives the load 30. The current detector 18 quantifies a signal proportional to the current outputted from the output stage 16 and outputs the result to the comparator 14. The voltage and current generator 1 thus constitutes a negative feedback loop both in the case of outputting a constant voltage and outputting a constant current.

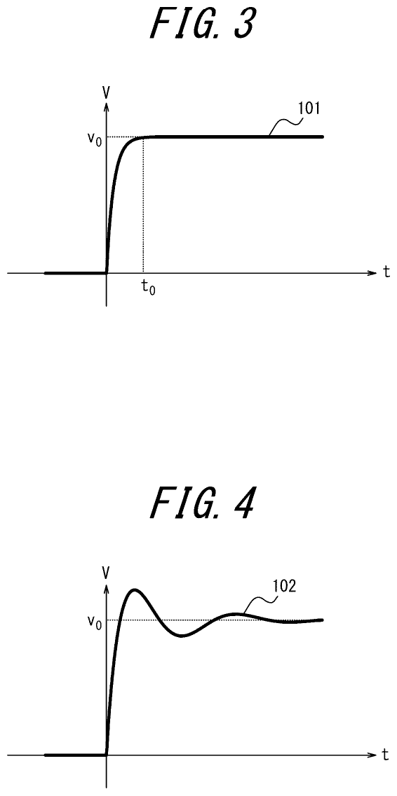

In a case in which a target value of output voltage or output current is set in the voltage and current generator 1, the desired response characteristics are such that overshooting and ringing are small, and the output voltage or output current is settled to the target value in a short time. The response characteristics in settling output voltage are explained below with reference to FIGS. 3 and 4.

FIG. 3 is a diagram illustrating an example of a graph 101 of an optimal output waveform in a typical source measure unit. In FIG. 3, the horizontal axis represents time, and the vertical axis represents voltage. In the example in FIG. 3, the graph 101 reaches the target value v₀ of voltage at time t₀, which is a short time. The desired characteristics are obtained by adjusting the characteristics of the control calculator 15 so that the combined characteristics of the control calculator 15 and the output stage 16 inside the voltage and current generator 1, the output resistance of the apparatus, and the response characteristics due to the load 30 outside the apparatus become first-order integral characteristics in a range such that one cycle gain is greater than one.

FIG. 4 is a diagram illustrating an example of a graph 102 of an output waveform with overshooting and ringing in a typical source measure unit. Overshooting refers to a large fluctuation, beyond the target value, in the value that is the control target (voltage, current, or the like). Ringing refers to the value that is the control target oscillating and fluctuating near the target value. When overshooting or ringing occurs for voltage or current, the settling time to the target value ends up increasing. For example, in a case in which the characteristics of the control calculator are defined so that the optimal response is obtained when there is no load, connecting a capacitor to the load reduces the phase margin and produces overshooting and ringing due to the integral characteristics (i.e., low-pass filter characteristics) caused by the output resistance of the output stage and the load capacitance.

To address this issue, the voltage and current generator 1 according to the present embodiment performs control including a compensation operation to cancel such a low-pass filter effect, thereby suppressing overshooting and ringing and shortening the settling time to the target value. For example, since the output resistance of the output stage 16 is known, the time constant can be calculated by knowing the capacity of load 30. Therefore, in addition to controlling the phase compensation according to the deviation of the voltage or current from the target value, the control calculator 15 performs control by adding the inverse characteristics of the low-pass filter due to the load 30 to achieve first-order integral characteristics, that is, optimal characteristics, for one cycle gain. As described below, the control calculator 15 achieves inverse characteristics that cancel the low-pass filter effect of the load 30 based on the impedance of the load 30 (for example, at least one of inductance L₁, capacitance C₁, and resistance R₃). Therefore, according to the voltage and current generator 1, improved output response of the source measure unit can be achieved with a simple setting.

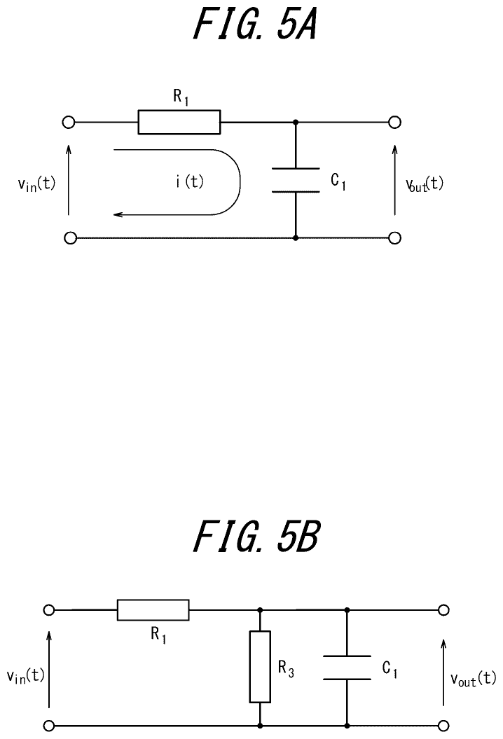

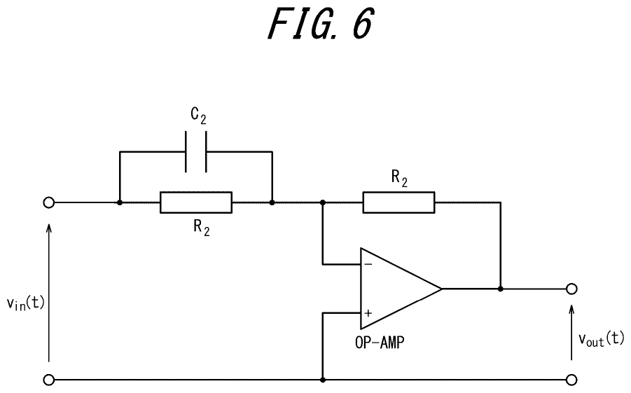

The process for achieving such inverse characteristics when outputting a constant voltage is explained with reference to FIGS. 5A, 5B, and 6. FIGS. 5A and 5B are diagrams illustrating a circuit configuration corresponding to the load 30 and the output resistance of the output stage 16. FIG. 5A illustrates a case in which the load 30 is formed only by the capacitance C₁, and FIG. 5B illustrates a case in which the load 30 is formed by a parallel circuit with the capacitance C₁ and the resistance R₃. FIGS. 5A and 5B illustrate an example of a case in which the output resistance of the output stage 16 and the impedance of the load 30 are replicated by an RC low-pass filter. To simplify the explanation, the case in which the load 30 is only the capacitance C₁ as illustrated in FIG. 5A is described here. The RC low-pass filter in FIG. 5A is a first-order low-pass filter consisting of the capacitance C₁ in parallel with the input signal and a resistance R₁ in series with the input signal. Let vᵢₙ(t) be the input voltage, vₒᵤₜ(t) be the output voltage, i(t) be the current flowing through the circuit, R₁ be the output resistance of the output stage 16, and C₁ be the capacitance of the capacitor in the load 30. In this case, the input voltage vᵢₙ(t) and the output voltage vₒᵤₜ(t) have a relationship such as in Equation 1.

$${v}_{in} ( t ) = {R}_{1} {C}_{1} {\dot{v}}_{out} ( t ) + {v}_{out} ( t ) \qquad [ Equation 1 ]$$

In Equation 1, \dot{v}ₒᵤₜ(t) is the derivative of vₒᵤₜ(t) at time t.

A Laplace transform of Equation 1 yields Equation 2.

$${V}_{out} ( s ) = \frac{1}{{R}_{1} {C}_{1} s + 1} {V}_{in} ( s ) \qquad [ Equation 2 ]$$

Here, setting the time constant τ=R₁C₁, the transfer function G(s) becomes Equation 3.

$$G ( s ) = \frac{1}{{R}_{1} {C}_{1} s + 1} = \frac{1}{τ s + 1} \qquad [ Equation 3 ]$$

The inverse function Gᵢₙᵥ(s) of the transfer function G(s) is expressed as in Equation 4.

$${G}_{inv} ( s ) = τ s + 1 \qquad [ Equation 4 ]$$

Therefore, by achieving the characteristics represented by the transfer function in Equation 4, the control calculator 15 can cancel the effect similar to a low-pass filter in the output stage 16 and the load 30, thereby suppressing overshooting and ringing of vₒᵤₜ(t) in FIG. 5A. FIG. 6 is a diagram illustrating an example of a circuit that provides such inverse characteristics of a low-pass filter. The circuit in FIG. 6 has the characteristics of Gᵢₙᵥ(s) except for phase inversion. In the circuit of FIG. 6, the input resistor and feedback resistor both have a resistance R₂. The capacitance of the capacitor in parallel with the input resistor is C₂. Here, R₂ and C₂ satisfy the requirements of Equation 5.

$${R}_{2} {C}_{2} = {R}_{1} {C}_{1} = τ \qquad [ Equation 5 ]$$

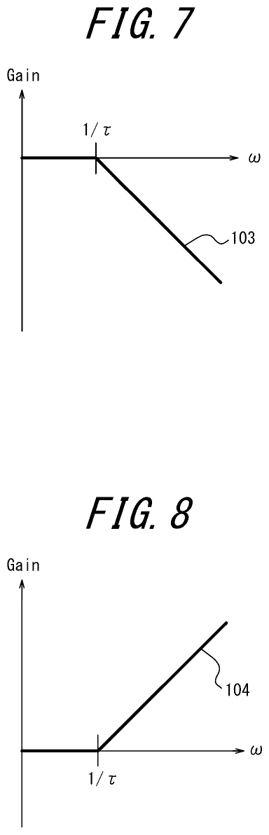

FIG. 7 is a diagram illustrating the gain characteristics of the load 30 in FIG. 5A. FIG. 8 is a diagram illustrating the gain characteristics of the circuit in FIG. 6. In other words, FIG. 7 illustrates a graph 103 of a gain diagram for the transfer function G(s), and FIG. 8 illustrates a graph 104 of a gain diagram for the inverse function Gᵢₙᵥ(s). In FIGS. 7 and 8, the horizontal axis represents the logarithm of the angular frequency ω, and the vertical axis represents the gain expressed in dB (decibels). In FIGS. 7 and 8, for simplicity, graphs 103 and 104 approximate the real gain diagrams with broken lines. As FIGS. 7 and 8 indicate, the angular frequency ω of the corners of the broken lines in graphs 103, 104 is ω=1/τ.

In FIG. 7, the graph 103 illustrates the first-order integral characteristics in a range in which the angular frequency ω is greater than 1/τ. By contrast, in FIG. 8, the graph 104 indicates the differential characteristics in a range in which the angular frequency ω is greater than 1/τ. Therefore, in a case in which the graph 104 in FIG. 8 is added to graph 103 in FIG. 7, the effects of the slopes of graphs 103 and 104 in the range in which the angular frequency ω is greater than 1/τ cancel each other out. In other words, the control of the inverse characteristics by the control calculator 15 corresponds to amplifying the signal in the range in which the angular frequency ω is greater than 1/τ. Since the phase of the output vₒᵤₜ(t) in the example of FIG. 6 is inverted from the input vᵢₙ(t), an inverting circuit may be provided downstream from the output vₒᵤₜ(t). Although FIG. 6 illustrates an example in which the inverse function Gᵢₙᵥ(s) is configured by analog elements, the control calculator 15 may achieve the inverse function Gᵢₙᵥ(s) by digital calculation.

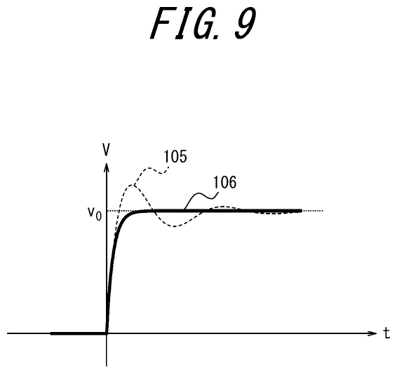

As described above, with respect to the effect as a first-order low-pass filter formed by a resistor with resistance R₁ and a capacitor with capacitance C₁, which occurs based on the impedance from the output resistance of the output stage 16 and the capacitance of the load 30 as in FIG. 5A, the control calculator 15 achieves a circuit, such as the one in FIG. 6, formed by a resistance R₂ and a capacitance C₂ with an equivalent time constant and can thereby cancel the integral characteristics in the output stage 16 and the load 30. FIG. 9 is a diagram illustrating an example of optimizing the graph 102 of the output waveform in FIG. 4. In FIG. 9, the horizontal axis represents time, and the vertical axis represents voltage. The graph 105 illustrates an example of an output waveform with overshooting and ringing. The graph 106 illustrates an example of an output waveform optimized by the control calculator 15 adding inverse characteristics that cancel out the characteristics of the output stage 16 and load 30 as a low-pass filter.

In this way, the voltage and current generator 1 acquires inverse characteristics that cancel the low-pass filter effect of the load 30 based on the impedance of the load 30 (for example, at least one of inductance L₁, capacitance C₁, and resistance R₃) and controls output of the electrical signal. Therefore, according to the voltage and current generator 1, improved output response of the source measure unit can be achieved with a simple setting.

In a case in which the voltage and current generator 1 outputs a constant voltage to the load 30 as described above, the capacitance C₁ of the load 30 and the output resistance R₁ of the output stage 16 act as a low-pass filter with a parallel circuit of capacitance C₁ and resistance R₁ connected thereto, as illustrated in FIG. 5A. Here, if the effect of the resistance R₃ in parallel with C₁ in the load 30 is also considered, as illustrated in FIG. 5B, the time constant τ of the low-pass filter due to the load 30 is τ=R₁×R₃/(R₁+R₃)×C₁. The control calculator 15 may therefore perform control of the inverse characteristics illustrated by the circuit in FIG. 6 for R₂ and C₂ such that R₂C₂=τ for a time constant τ(τ=R₁×R₃/(R₁+R₃)×C₁) that also takes into account the resistance R₃ in addition to the capacitance C₁ of the load 30 and the output resistance R₁ of the output stage 16. According to this configuration, the voltage and current generator 1 can settle the output voltage to the target value in a shorter time while suppressing overshooting and ringing by more precise control using the known output resistance R₁ and impedance of the load 30. In addition, operation is easier, since the user only needs to input the capacitance C₁ and resistance R₃ of the load 30.

In the case of outputting a constant current to the load 30, the voltage and current generator 1 can also establish the output current in a short time by performing control to cancel the low-pass filter effect of the load 30, as in the case of outputting a constant voltage. Specifically, in the case of constant current output, the load 30 acts as a low-pass filter with a time constant τ of τ=L₁/(R₁+R₃) for the known output resistance R₁ of the output stage 16, the load resistance R₃ in the load 30, and the inductance L₁ in series with R₁ and R₃. The control calculator 15 may therefore perform control for inverse characteristics that cancel out such a low-pass filter effect of the load 30. According to this configuration, the voltage and current generator 1 can settle the output current to the target value in a shorter time while suppressing overshooting and ringing by more precise control using the known output resistance R₁. In addition, operation is easier, since the user only needs to input the resistance R₃ of the load 30 and the inductance L₁ that is in series with the resistance R₃. As in the case of generating a constant current, the control calculator 15 may achieve control of the inverse characteristics by digital calculation.

The user of the voltage and current generator 1 can thus have the voltage and current generator 1 generate a constant voltage and a constant current with a short settling time by simply inputting the inductance L₁, capacitance C₁, and resistance R₃ of the load 30, without needing to know the output resistance R₁ of the voltage and current generator 1. The voltage and current generator 1 may also store the output resistance R₁ for each range of output in advance and control the inverse characteristics to cancel the low-pass filter effect of the load 30 using the output resistance R₁ according to the voltage or current range selected by the user. According to this configuration, even if the output resistance R₁ of the output stage 16 changes as the range is changed, the voltage and current generator 1 can maintain an optimal regulation state with a short settling time, with no overshooting or ringing, without the user having to perform any operations to change the settings. Therefore, even in a case in which a function known as auto-range, i.e., a function to select the optimal range according to the measured value, is introduced into the voltage and current generator 1, for example, the user can have the voltage and current generator 1 automatically select the range simply by setting the impedance of the load 30.

Operations in the case in which the load 30 is connected to the voltage and current generator 1, as illustrated in FIG. 2, have been described thus far. Operations may become unstable, however, if the control calculator 15 performs the control to add the inverse characteristics of the low-pass filter when no load 30 is connected to the voltage and current generator 1. For example, if the control calculator 15 performs the control to add the inverse characteristics as illustrated in FIG. 8 while the output terminal of the output stage 16 is open during operations for voltage generation, the gain in the high frequency range becomes excessive in the absence of the low-pass filter effect in the one cycle loop illustrated in FIG. 7. As a result, operations of the voltage and current generator 1 may become unstable. In a case in which the control calculator 15 performs control to provide the inverse characteristics while the output terminal of the output stage 16 is short-circuited during operations for current generation, operations of the voltage and current generator 1 may also become unstable due to excessive gain in the high frequency range in the absence of the low-pass filter effect.

To prevent this phenomenon, the voltage and current generator 1 may adjust the control calculator 15 to limit the maximum value of the gain of the inverse characteristics being added and to reduce the loop bandwidth when setting the load. This enables the voltage and current generator 1 to maintain stable operations, rather than oscillating or otherwise becoming unstable, even if the load 30 is unexpectedly disconnected. Even in the case of such adjustment of the control calculator 15, the only parameter that the user needs to set for the voltage and current generator 1 is the impedance of the externally connected load 30. In other words, the user only needs to set at least one of the following values for the load 30: the load resistance R₃, the capacitance C₁ in parallel with the load resistance R₃, and the inductance L₁ in series with the load resistance R₃.

As described above, the voltage and current generator 1 according to the present embodiment includes the operation interface 11, the output stage 16, the detector (17, 18), and the control calculator 15. The operation interface 11 receives an operation from the user. The output stage 16 outputs an electrical signal to the load 30. The detector (17, 18) detects a measured value of the electrical signal outputted by the output stage 16. The control calculator 15 controls operation of the output stage 16, based on a deviation between a target value of the electrical signal as set by the user via the operation interface 11 and the measured value of the electrical signal as detected by the detector (17, 18), so that the measured value of the electrical signal approaches the target value. The control calculator 15 performs control, including a compensation operation to cancel a low-pass filter effect in the output resistance of the output stage 16 and the load 30, based on an impedance of the load 30 as set by the user via the operation interface 11. The user can therefore improve the output response of the voltage and current generator 1 by performing a simple setting, without having to consider the output resistance R₁ of the output stage 16, which is difficult to know from the outside.

Even if the impedance of the load 30 as set by the user is not necessarily accurate, the voltage and current generator 1 can adjust the characteristics to become first-order integral characteristics in a range in which the one cycle gain is greater than 1 by adding inverse characteristics corresponding to the impedance to the electrical signal characteristics. Therefore, the user can improve the output response of the voltage and current generator 1 by simply entering an approximately value, even if the exact impedance of the load 30 is not known.

The control calculator 15 may also perform control to cancel the low-pass filter effect in the output stage 16 and the load 30 based on the output resistance R₁ according to the range of the electrical signal set by the user via the operation interface 11. The output response of the voltage and current generator 1 can therefore be improved through precise control without the user having to set the output resistance R₁, which is difficult for the user to know externally, that corresponds to the range.

The output stage 16 may output a constant voltage signal as an electrical signal to the load 30. The voltage detector 17 may detect the voltage value of the electrical signal outputted by the output stage 16 as a measured value. The control calculator 15 may control operation of the output stage 16 based on a deviation between a target value of voltage of the electrical signal as set by the user via the operation interface 11 and the voltage value of the electrical signal as detected by the voltage detector 17. The control calculator 15 may perform control, including the compensation operation to cancel the low-pass filter effect in the output stage 16 and the load 30, based on a resistance and a capacitance of the load 30 as set by the user via the operation interface 11 as the impedance of the load 30. The user can therefore improve the constant voltage output response of the voltage and current generator 1 by performing a simple setting.

The output stage 16 may output a constant current signal as an electrical signal to the load 30. The current detector 18 may detect the voltage value of the electrical signal outputted by the output stage 16 as a measured value. The control calculator 15 may control operation of the output stage 16 based on a deviation between a target value of current of the electrical signal as set by the user via the operation interface 11 and the current value of the electrical signal as detected by the current detector 18. The control calculator 15 may perform control, including the compensation operation to cancel the low-pass filter effect in the output stage 16 and the load 30, based on a resistance and an inductance of the load 30 as set by the user via the operation interface 11 as the impedance of the load 30. The user can therefore improve the constant current output response of the voltage and current generator 1 by performing a simple setting.

As the control to cancel the low-pass filter effect in the load 30, the control calculator 15 may perform control adjusted to add a characteristic limiting a maximum gain for the electrical signal in a band greater than a predetermined frequency, and to decrease the gain over the entire band. The operation of the voltage and current generator 1 can therefore be prevented from becoming unstable even in a case in which no load 30 is connected to the voltage and current generator 1.

As described above, the present embodiment enables a voltage and current generator 1 that applies voltage and current to achieve a fast and stable response while suppressing the effect of the impedance of the connection target. The only operation required of the user is to input the impedance (L₁, C₁, R₃) of the load 30 to be connected. The electrical signal can thus be settled by a simple and easy-to-understand operation.

The present disclosure is not limited to the above embodiments. For example, a plurality of blocks described in the block diagrams may be integrated, or a block may be divided. Other modifications can be made without departing from the spirit of the present disclosure.

1. A voltage and current generator comprising:
an operation interface configured to receive an operation from a user;
an output stage configured to output an electrical signal to a load;
a detector configured to detect a measured value of the electrical signal outputted by the output stage; and
a control calculator configured to control operation of the output stage, based on a deviation between a target value of the electrical signal as set by the user via the operation interface and the measured value of the electrical signal as detected by the detector, so that the measured value of the electrical signal approaches the target value, wherein
the control calculator is configured to perform control, including a compensation operation to cancel a low-pass filter effect in output resistance of the output stage and the load, based on an impedance of the load as set by the user via the operation interface.

2. The voltage and current generator according to claim 1, wherein the control calculator is configured to perform the control, including the compensation operation to cancel the low-pass filter effect in the output resistance and the load, based on the output resistance of the output stage corresponding to a range of the electrical signal as set by the user via the operation interface.

3. The voltage and current generator according to claim 1, wherein
the output stage is configured to output a constant voltage signal as the electrical signal to the load,
the detector is configured to detect a voltage value of the electrical signal outputted by the output stage as the measured value, and
the control calculator is configured to
control operation of the output stage based on a deviation between a target value of voltage of the electrical signal as set by the user via the operation interface and the voltage value of the electrical signal as detected by the detector, and
perform control, including the compensation operation to cancel the low-pass filter effect in the output resistance and the load, based on a resistance and a capacitance of the load as set by the user via the operation interface as the impedance of the load.

4. The voltage and current generator according to claim 1, wherein
the output stage is configured to output a constant current signal as the electrical signal to the load,
the detector is configured to detect a current value of the electrical signal outputted by the output stage as the measured value, and
the control calculator is configured to
control operation of the output stage based on a deviation between a target value of current of the electrical signal as set by the user via the operation interface and the current value of the electrical signal as detected by the detector, and
perform control, including the compensation operation to cancel the low-pass filter effect in the output resistance and the load, based on a resistance and an inductance of the load as set by the user via the operation interface as the impedance of the load.

5. The voltage and current generator according to claim 1, wherein as the control to cancel the low-pass filter effect in the load, the control calculator is configured to perform control adjusted to add a characteristic limiting a maximum gain for the electrical signal in a band greater than a predetermined frequency.
